(19) United States
(12) Patent Application Publication
(10) Pub. No.: US 2008/0093338 A1
(43) Pub. Date: Apr. 24, 2008

(54) Dry Etching Method And Dry Etching Apparatus

(76) Inventors: Mitsuhiro Okune, Nara (JP); Hiroyuki Suzuki, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/792,238

(22) PCT Filed: Dec. 6, 2005
(86) PCT No.: PCT/JP05/22351

§ 371 Date: Jun. 4, 2007

(30) Foreign Application Priority Data
Dec. 6, 2004 (JP) 2004-352614

(51) Int. Cl. H01L 21/306; B44C 1/22

(52) U.S. Cl. 216/41; 156/345.24

(57) ABSTRACT

An object of the present invention is suppressing notches in dry etching of a processing object where an etched layer made of a silicon material is formed on an etching stop layer. A substrate 12 has an etched layer 22 made of a silicon material on an etching stop layer 21. SF₆/C₄F₈ gas, as an etching gas, is supplied to generate plasma, and a portion of the etched layer exposed through a resist mask 23 is etched. A sidewall protection layer 24 made of polymer is formed on a sidewall of a trench or hole.

### TECHNICAL FIELD

The present invention relates to a dry etching method and a dry etching apparatus.

### BACKGROUND ART

In dry etching for forming hole such as trench or via hole in a processing object having an etched layer made of a silicon material formed on an etching stop layer, there can be a phenomena where a sidewall of the trench or hole near an interface between the etched layer and etching stop layer is etched (notch). The mechanism for generation of the notch is described in Patent Publication 1.

With reference to FIGS. 6A and 6B, the mechanism for generation of the notch when dry etching is performed on a substrate with an SOI (Silicon On Insulator) structure using SF₆/O₂ (sulfur hexafluoride/oxygen) etching gas will be described. An etched layer 2 made of silicon material (e.g. Si) is formed on an etching stop layer 1 made of SiO₂ (silicon dioxide). A resist mask 3 is formed on the etched layer 2.

As shown in FIG. 6A shows, an F component, F radicals, and O component, generated by plasma, enter a portion of the etched exposed layer 2 through the resist mask 3. The etched layer 2 is etched by the F radicals and positive ions (e.g. S ions and O ions) as etching seeds. At this time, the F radicals and the etched layer 2 react with Si atoms to generate SiF₄ (silicon tetrafluoride) and SiF₆ (silicon hexafluoride) which are volatile reaction products, and then the SiF4 and SiF6 leave from the etched layer 2. The O component reacts with the Si atoms of the silicon material constituting the etched layer 2 to generate SiO₂ (silicon dioxide), and then the SiO₂ adsorbs to the sidewall of the trench or hole to form a sidewall protection layer 4. By this sidewall protection layer 4, erosion of the sidewall of the trench or hole by the F radicals and positive ions is prevented.

However, if the etching stop layer 1 is exposed due to that the trench or hole penetrates the etched layer 2, because the supply of Si atoms from the etched layer 2 stops, SiO₂ is not generated. This results in that the sidewall protection layer 4 is not formed on the sidewall of the trench or hole, and silicon material remains exposed in an area near the interface between the etched layer 2 and the etching stop layer 1. On the other hand, because the exposed portion of the etching stop layer 1 is charged to positive polarity by incident positive ions, the orbits of the incident positive ions are curved, resulting in that the ions are directed to the sidewall of the trench or hole. Because the sidewall protection layers 4 are not formed, the sidewall of the trench or hole are eroded by the positive ions of which orbits are curved, resulting in that the notches 5 are generated as shown in FIG. 6B. The notches 5 decrease the processing precision of the trench or hole.

[Patent Publication] Japanese Paten Application Laid-Open Publication No. H9-82682

### DISCLOSURE OF INVENTION

### Problem to be Solved by the Invention

It is an object of the present invention to suppress the notches in dry etching of a processing object having an etched layer made of a silicon material and formed on an etching stop layer.

### Means for Solving the Problem

A first aspect of the invention provides a dry etching method, comprising, placing a processing object in a vacuum container, the processing object being provided with a etching stop layer on which an etched layer made of a silicon material is formed, and a mask being formed on a surface of the etched layer, supplying etching gas into the vacuum container, the etching gas containing a first gas component for generating etching seeds of the etched layer when plasma is generated and a second gas component which is a fluorocarbon gas, and generating plasma in the vacuum container to etch a portion of the surface of the etched layer exposed through the mask by the etching seeds generated by the first gas component.

The silicon materials include Si (mono crystal silicon), poly-Si (polysilicon), a-Si (amorphous silicon), WSi (tungsten silicide), MoSi (molybdenum silicide) and TiSi (titanium silicide), whereas the silicon materials do not include SiO₂ (silicon dioxide).

The etched layer made of a silicon material is etched by the etching seeds from the first gas component. Polymer is generated by the second gas component which is fluorocarbon gas, and the polymer adsorbs to the sidewall of etched trench or hole to create a sidewall protection layer. The polymer by the second gas component is generated regardless the occurrence of a reaction with Si atoms of the silicon material constituting the etched layer, resulting in that the sidewall protection layer is formed on the sidewall of the etched trench or hole from the surface of the etched layer to the interface with the etching stop layer. Therefore even after the trench or hole penetrates the etched layer made of silicon material, notches near the interface between the etched layer and the etching stop layer can be suppressed.

The second gas component, which is a fluorocarbon gas, contains at least one of C₄F₈ (octafluorocyclobutane), CHF₃ (trifluoromethane), C₅F₈ (perfluorocyclopentene) and C₄F₆ (hexafluorocyclobutane), for example.

The first gas component can be any gas which generates etching seeds of silicon material when plasma is generated. The first gas component is, for example, SF₆ (sulfur hexafluoride). The first gas component may also be CF₄ (tetrafluoromethane), C₃F₆ (hexafluoropropylene), or NF₃ (nitrogen trifluoride).

A combination of the etched layer and the etching stop layer can be Si in the former and SiO₂ in the latter, which is an SOI structure. The etching stop layer can also be SiON (silicon oxynitride) or SiN (silicon nitride).

A second aspect of the invention provides A dry etching method, comprising, placing a processing object in a vacuum container, the processing object being provided with a etching stop layer on which an etched layer made of a silicon material is formed, and a mask being formed on a surface of the etched layer, supplying a first etching gas into the vacuum container, the first etching gas containing a first gas component for generating etching seeds of the etched layer when plasma is generated and a second gas component for generating an adsorption product by reacting with atoms of the silicon material constituting the etched layer, generating plasma in the vacuum container to etch a portion of the surface of the etched layer exposed through the mask by the etching seeds generated by the first gas component, supplying a second etching gas after stopping the etching by the first etching gas, the second etching gas containing the first gas component and a third gas component which is a fluorocarbon gas, and generating plasma in the vacuum container to etch a portion of the surface of the etched layer exposed through the mask by the etching seeds generated by the first gas component.

During etching by the first etching gas, the etched layer is etched by the etching seeds from the first gas component contained in the first etching gas. Further, during etching by the first etching gas, the second gas component contained in the first etching gas reacts with the Si atoms in the etched layer and an adsorption product is generated, and this reaction product adsorbs to the sidewall of the etched trench or hole to become the sidewall protection layer. When the etching gas is switched from the first etching gas to the second etching gas, the etched layer is etched by the etching seeds from the first gas component contained in the second etching gas. Further, polymer is generated by the third gas component, which is a fluorocarbon gas, contained in the second etching gas, and this polymer forms the sidewall protection layer. Therefore, formed at a surface side of the sidewall of the trench or hole is the sidewall protection layer made of the reaction product of the second gas component and the Si atoms, whereas formed at an etching stop layer side of the sidewall of the trench or hole is the sidewall protection layer made of polymer. The polymer by the third gas component is generated regardless the occurrence of a reaction with the Si atoms of the silicon material constituting the etched layer, resulting in that the sidewall protection layer made of polymer is formed even at the interface between the etched layer and the etching stop layer. Therefore, even after the trench or hole penetrates the etched layer made of silicon material, notches near the interface between the etched layer and the etching stop layer can be suppressed.

For example, the gas used for the etching is switched from the first etching gas to the second etching gas after an etching depth of the etched layer reaches 50% or more of a thickness of the etched layer and before the etching depth reaches an interface between the etched layer and the etching stop layer

A third aspect of the invention provides a dry etching apparatus, comprising, a vacuum container in which a processing object is placed, the processing object being provided with a etching stop layer on which an etched layer made of a silicon material is formed, and a mask being formed on a surface of the etched layer, a first etching gas supply adapted to supply a first etching gas into the vacuum container, the first etching gas containing a first gas component for generating etching seeds of the etched layer and a second gas component for generating an adsorption product by reacting with atoms of the silicon material constituting the etched layer, a second etching gas supply adapted to supply a second etching gas into the vacuum container, the second etching gas containing the first gas component and a third gas component which is a fluorocarbon gas, a plasma generation source for generating plasma in the vacuum container, and a controller for controlling the first and second etching gas supplies and the plasma generation source so as to continue a status where the first etching gas supply supplies the first etching gas into the vacuum container and the plasma generation source generates plasma in the vacuum container for a predetermined first time, and then to continue a status where the second etching gas supply supplies the second etching gas into the vacuum container and the plasma generation source generates plasma in the vacuum container for a predetermined second time.

It is preferable that the dry etching apparatus further comprises a guide element for holding the processing object, wherein the guide element is made of fluororesin.

F radicals generated by plasma are not consumed by the guide ring, but efficiently enter the processing object. This results in that the time based fluctuation of the etching rate is suppressed and that a high etching rate can be obtained.

### EFFECT OF THE INVENTION

According to the present invention, polymer is generated by the fluorocarbon gas contained in the etching gas, and this polymer adsorbs to the sidewall of the etched trench or hole to form the sidewall protection layer. This polymer is generated regardless the occurrence of a reaction with the Si atoms of the silicon material constituting the etched layer, resulting in that the sidewall protection layer made of polymer is also formed in an area near the interface between the etched layer and the etching stop layer. Therefore, even after the trench or hole penetrates the etched layer, notches near the interface between the etched layer and the etching stop layer can be suppressed.

### BRIEF DESCRIPTION OF THE DRAWINGS

FIG. 1 is a schematic diagram of an apparatus for a dry etching method according to a first embodiment of the present invention;

FIG. 2 is an enlarged view of a part of the dry etching apparatus;

FIG. 3A is a schematic view of a status of a substrate before an etching depth reaches an etching stop layer in a dry etching method according to the first embodiment;

FIG. 3B is a schematic view of a status of the substrate when the etching depth reaches the etching stop layer in the dry etching method according to the first embodiment;

FIG. 4 is a schematic diagram of an apparatus for a dry etching method according to a second embodiment of the present invention;

FIG. 5A is a schematic view of a status of the substrate during etching by SF₆/O₂ gas in a dry etching method according to the second embodiment;

FIG. 5B is a schematic view of a status of the substrate during etching by SF₆/C₄F₈ gas in the dry etching method according to the second embodiment;

FIG. 6A is a schematic view of a status of a substrate before an etching depth reaches an etching stop layer according to a conventional dry etching method; and

FIG. 6B is a diagram depicting a status of the substrate when the etching depth reaches the etching stop layer according to the conventional dry etching method.

### DESCRIPTION OF REFERENCE NUMERALS

11: dry etching apparatus
12: substrate
13: chamber
13a: gas inlet
13b: outlet
14A, 14B: high frequency power supply
15: upper electrode
16: lower electrode
17: guide ring
18, 18A, 18B: etching gas supply
19: vacuum pumping device
20: controller
21: etching stop layer
22: etched layer
23: resist mask
24, 24A, 24B: sidewall protection layer
P: plasma.

### BEST MODE FOR CARRYING OUT THE INVENTION

### First Embodiment

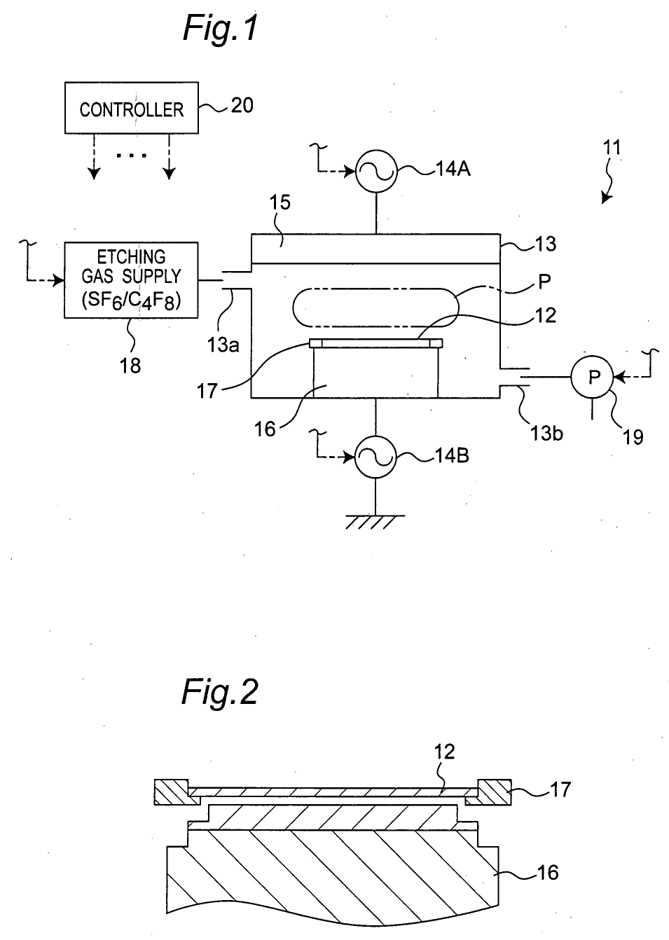

FIG. 1 shows an example of an apparatus used for a dry etching method according to a first embodiment of the present invention.

The dry etching apparatus 11 has a chamber (vacuum container) 13 in which a substrate (processing object) 12 is placed. Disposed in an upper area within the chamber 13 is an upper electrode 15 electrically connected to a high frequency power supply 14A. Disposed in a lower area within the chamber 13 is a lower electrode 16 electrically connected to a high frequency power supply 14B. A substrate 12 is placed on the lower electrode 16.

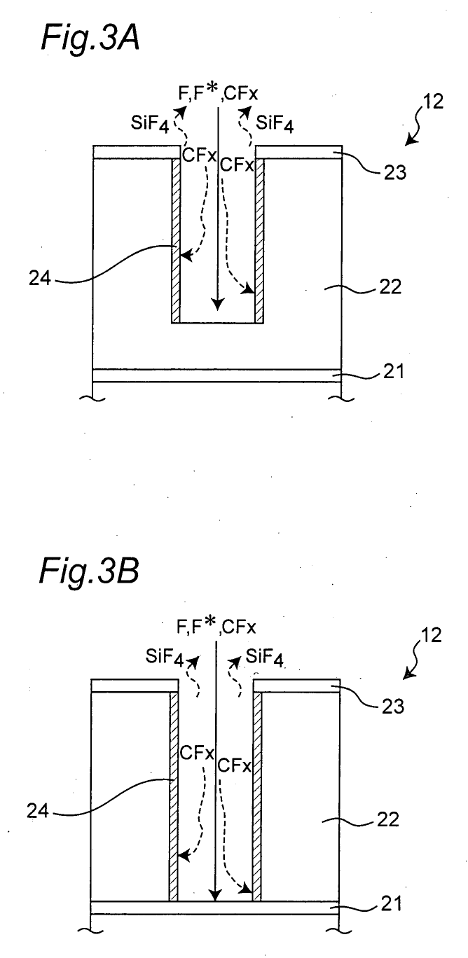

Further referring to FIG. 3A, the substrate 12 is provided with an etching stop layer 21 made of SiO₂ (silicon dioxide) on which an etched layer 22 made of Si as an example of a silicon material is formed. A resist mask 23 is formed on the etched layer 22 in a desired pattern.

As shown in FIG. 2, the substrate 12 is held by a guide ring 17 for positioning so as to be placed on the lower electrode 16. The guide ring 17 is made of fluororesin or Teflon such as PTF (polytetrafluoroethylene), FEP (fluorinated ethylene propylene) and ETFE (ethylene tetrafluoroethylene).

An etching gas supply 18 is fluidly connected to a gas inlet 13a of the chamber 13. In the present embodiment, an etching gas to be supplied from the etching gas supply 18 is SF₆/C₄F₈ (sulfur hexafluoride/octafluorocyclobutane) gas. As described later, SF₆ contained in the etching gas generates etching seeds of the etched layer 22 when plasma is generated. Further, when plasma is generated, a protective layer is formed on the sidewall of an etched trench or hole by C₄F₈ which is a fluorocarbon gas.

A vacuum pumping device 19 is fluidly connected to an outlet 13b of the chamber 13.

A controller 20 controls the first and second high frequency power supplies 14A and 14B, the etching gas supply 18, and the vacuum pumping device 19 for executing dry etching.

Then, the dry etching method according to the present embodiment will be described.

First, the substrate 12 is held by the guiding ring 17 and placed on the lower electrode 16 within the chamber 13. Then, while supplying SF₆/C₄F₈ gas as the etching gas from the etching gas supply 18 at a predetermined flow rate, air is exhausted by the vacuum pumping device 19 at a predetermined flow rate, so as to maintain a pressure inside the chamber 13 at a predetermined pressure.

High frequency power is supplied to the upper electrode 15 and the lower electrode 16 from the first and second high frequency power supplies 14A and 14B. As a result, plasma “P” is generated, as shown in FIG. 1. In the plasma “P”, an F component and F radicals are generated from the SF₆ contained in the etching gas, and a fluorocarbon component (CFₓ) is generated from C₄F₈. Positive ions (S ions, O ions, carbon fluoride ions, and sulfur fluoride ions) are also generated.

As shown if FIG. 3A, the F component, F radicals, positive ions, and fluorocarbon components enter a portion of the etched layer 22 exposed through the resist mask 23, and then the etched layer 22 is etched by the F radicals and positive ions as the etching seeds. At this time, SiF₄ (sulfur tetrafluoride), which is a volatile reaction product, is generated by reaction of the F radicals and Si atoms of the etched layer 22, and the SiF₄ leaves the etched layer 22. Also fluorocarbon polymer ((CF₂)ₙ) is generated by the CFₓ component, and the fluorocarbon polymer adsorbs to the sidewall of the etched trench or hole to form a sidewall protection layer 24.

The fluorocarbon polymer is generated regardless the occurrence of a reaction with the Si atoms of the etched layer 22. Thus, even if the trench or hole penetrates the etched layer 22 resulting in that the etching stop layer 21 is exposed, the sidewall protection layer 24 is continuously formed on the sidewall of the trench or hole. Therefore, as shown in FIG. 3B, the sidewall protection layer 24 is formed on the sidewall of the etched trench or hole, from the surface of the etched layer 22 to an interface with the etching stop layer 21. By the presence of this sidewall protection layer 24, the sidewall near the interface with the etching stop layer 21 is protected from erosion by the positive ions and F radicals even after the trench or hole penetrates the etched layer 22, resulting in that notches are suppressed.

Given that guide ring 17 is made of SiO₂ for example, a part of the F radicals generated by the plasma “P” is consumed by the reaction with Si contained in the guide ring 17, and an efficiency of incidence of the F radicals to the substrate 12 drops accordingly, causing that the time-based fluctuation and drop in the etching rate are generated. However, because the guide ring 17 of the present embodiment is not made of a silicon material but of fluororesin, as mentioned above, the F radicals generated by the plasma “P” is not consumed by the guide ring 17, but efficiently enter the substrate 12. As a result, the time-based fluctuation of the etching rate can be suppressed and a high etching rate can be obtained.

### Second Embodiment

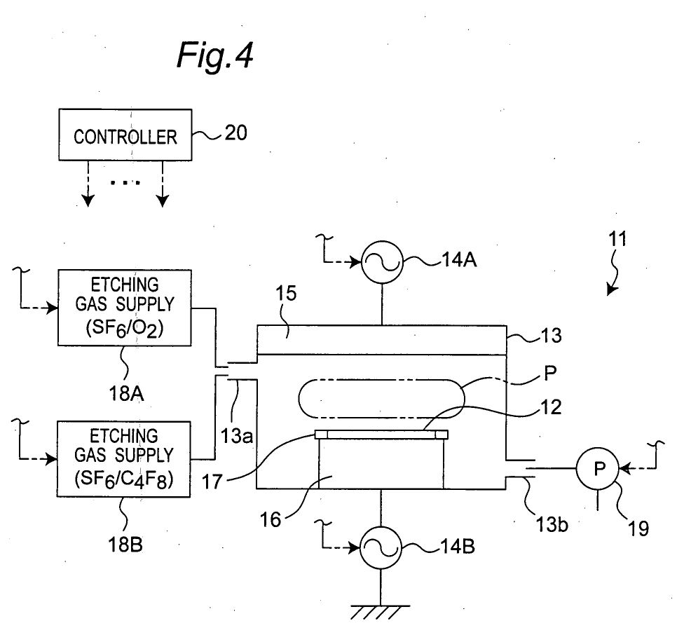

FIG. 4 shows an example of an apparatus for a dry etching method according to a second embodiment of the present invention. Similarly to the first embodiment, the substrate 12 is provided with the etching stop layer made of SiO₂, the etched layer 22 made to Si formed on the etched layer 22, and the resist mask 23 formed on the etched surface in a desired pattern.

The difference of this dry etching apparatus 11 from that of the first embodiment is that this dry etching apparatus 11 has two etching gas supplies, i.e., a first etching gas supply 18A and a second etching gas supply 18B.

The first etching gas supply 18A supplies SF₆/O₂ (sulfur hexafluoride/oxygen) gas into a chamber 13 as an etching gas. As described later, SF₆ contained in the etching gas from the first etching gas supply 18A generates etching seeds of the etched layer 22 made of Si when the plasma is generated. Further, an O component contained in the etching gas reacts with the Si atoms of the etched layer 22 to generate SiO₂.

On the other hand, the second etching gas supply 18B supplies SF₆/C₄F₈ gas into the chamber 13 as an etching gas similarly to the etching gas supply 18 of the first embodiment. When the plasma is generated, etching seeds are generated primarily by SF₆ contained in the etching gas from the second etching gas supply 18B, and fluorocarbon polymer is generated by C₄F₈.

Then, the dry etching method according to the present embodiment will be described.

After the substrate 12 is held by the guide ring 17 on the lower electrode 16, while supplying SF₆/O₂ gas as the etching gas at a predetermined flow rate from the first etching gas supply 18A, air is exhausted by the vacuum pumping device 19 at a predetermined flow rate, so as to maintain a pressure inside the chamber 13 at a predetermined pressure.

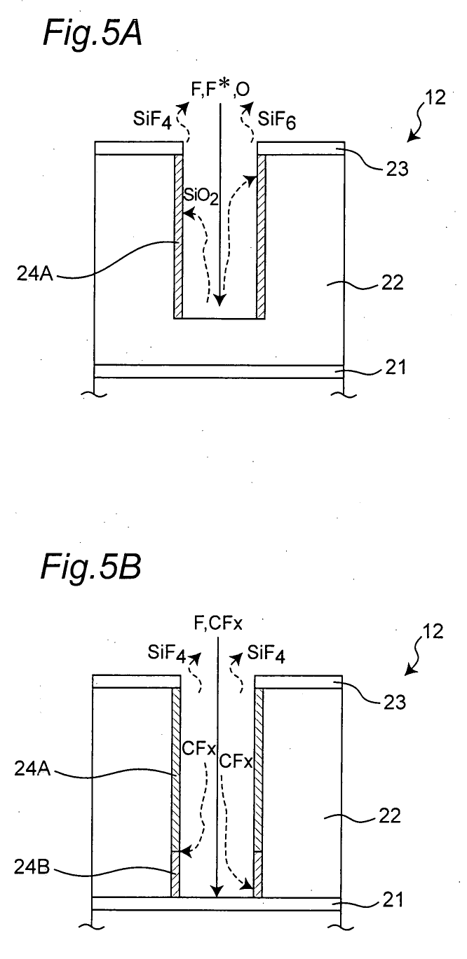

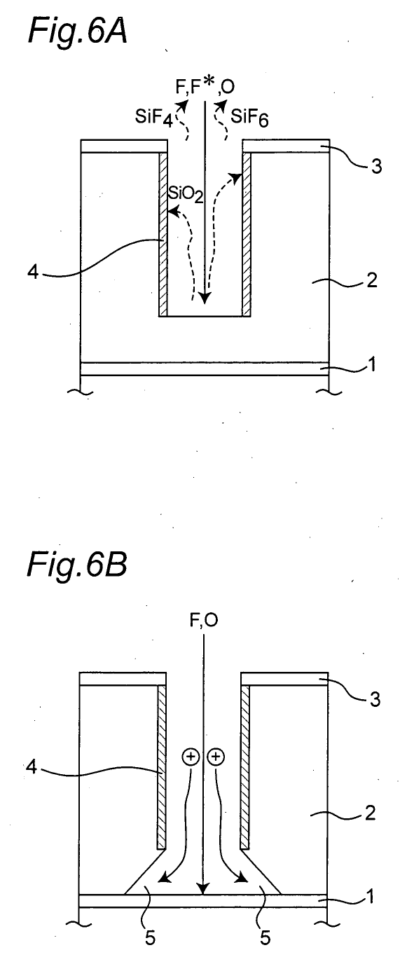

High frequency power is supplied to the upper electrode 15 and lower electrode 16 from the first and second high frequency power supplies 14A and 14B to generate the plasma “P”. In the plasma “P”, an F component, F radicals, and positive ions (e.g. S ions and sulfur fluoride ions) are generated from SF₆ contained in the etching gas. As shown in FIG. 5A, the F components, F radicals, positive ions and O components enter a portion of the etched layer 22 exposed through the resist mask 23, and then the etched layer 22 is etched by the F radicals and positive ions. This results in that volatile SiF₄ and SiF₆ are generated and leave the etched layer 22. The O component reacts with the Si atoms of the silicon material constituting the etched layer 22, and SiO₂ (silicon dioxide) is generated, and this SiO₂ adsorbs to the sidewall of the trench or hole to form a sidewall protection layer 24A.

After continuing etching by SF₆/O₂ gas for a predetermined time, the supply of SF₆/O₂ gas from the first etching gas supply 18A is stopped, and at the substantially same time the supply of SF₆/C₄F₈ gas from the second etching gas supply 18B is started to perform etching by SF₆/C₄F₈ gas. At this time, the power supply from the high frequency power supplies 14A and 14B to the upper and lower electrodes 15 and 16 may be stopped temporarily. The timing for switching the etching gases is set such that a final stage of the etching, which is the etching of the etched layer 22 near the interface with the etching stop layer 21, is performed not by SF₆/O₂ gas but by SF₆/C₄F₈ gas. For example, the gas used for the etching is switched from the SF₆/O₂ gas to the SF₆/C₄F₈ gas after an etching depth of the trench or hole reaches 50% or more of a thickness of the etched layer 22, and before this etching depth reaches the interface between the etched layer 22 and the etching stop layer 21.

During etching by the SF₆/C₄F₈ gas, the F component, F radicals, and positive ions (e.g. S ions, carbon fluoride ions, and sulfur fluoride ions) are generated from SF₆, and a CFₓ component is generated from C₄F₈. As shown in FIG. 5B, the F component, F radicals, positive ions, and CFₓ component enter the portion of the etched layer 22 exposed through the resist mask 23, and thus the etched layer 22 is etched by the F radicals and positive ions, which are the etching seeds, and SiF₄, which is a volatile reaction product, leaves the etched layer 22. Further, a fluorocarbon polymer is generated by the CFₓ component, and the fluorocarbon polymer adsorbs to the sidewall of the etched trench or hole to form the sidewall protection layer 24B. As mentioned above, because the fluorocarbon polymer is generated regardless the occurrence of the reaction with the Si atoms of the etched layer 22, even if the trench or hole penetrates the etched layer 22 and the etching stop layer 21 is exposed, the sidewall protection layer 24B is continuously formed on the sidewall of the trench or hole. Therefore, as shown in FIG. 5B, the sidewall protection layer 24B reaches the interface with the etching stop layer 21. By the presence of this sidewall protection layer 24B, the sidewall near the interfaced with the etching stop layer 21 are protected from erosion by the positive ions and F radicals, even after the trench or hole penetrates the etched layer 22, resulting in that notches are suppressed. As shown in FIG. 5B, formed at a surface side of the sidewall of the trench or hole is the sidewall protection layer made of SiO₂, whereas formed at etching stop layer 21 side of the sidewall is the sidewall protection layer 24B made of fluorocarbon polymer

An etching rate when the SF₆/O₂ gas is used is faster than that when the SF₆/C₄F₈ gas is used. Therefore, by using the SF₆/C₄F₈ gas only for the final stage of the etching, time required from the start to the end of etching can be decreased.

The present invention is not limited to the above embodiments, but various modifications are possible. For example, the silicon material constituting the etched layer may be Poly-Si (polysilicon), a-Si (amorphous silicon), WSi (tungsten silicide), MoSi (molybdenum silicide), or TiSi (titanium silicide).

The etching gas may contain CHF₃ (trifluoromethane), C₅F₈ (perfluorocyclopentene) or C₄F₆ (hexafluorocyclobutane) as a fluorocarbon gas.

The gas component for generating etching seeds of silicon material contained in the etching gas may be CF₄ (tetrafluoromethane), C₃F₆ (hexafluoropropylene), or NF₃ (nitrogen trifluoride) for example.

The dry etching apparatus used for the method of the present invention is not limited to those of the embodiments.

The present invention was described in detail with reference to the accompanying drawings, but the present invention can be changed and modified in various ways by those who skilled in the art. These changes and modifications within the spirit and scope of the present invention shall be included in the present invention.

1. A dry etching method, comprising:
placing a processing object in a vacuum container, the processing object being provided with a etching stop layer on which an etched layer made of a silicon material is formed, and a mask being formed on a surface of the etched layer;
supplying etching gas into the vacuum container, the etching gas containing a first gas component for generating etching seeds of the etched layer when plasma is generated and a second gas component which is a fluorocarbon gas; and
generating plasma in the vacuum container to etch a portion of the surface of the etched layer exposed through the mask by the etching seeds generated by the first gas component.

2. The dry etching method according to claim 1, wherein the second gas component contains at least one of C₄F₈, CHF₃, C₅F₈ and C₄F₆.

3. The dry etching method according to claim 1, wherein the first gas component is SF₆.

4. The dry etching method according to claim 1, wherein the etched layer is Si and the etching stop layer is SiO₂.

5. A dry etching method, comprising:
placing a processing object in a vacuum container, the processing object being provided with a etching stop layer on which an etched layer made of a silicon material is formed, and a mask being formed on a surface of the etched layer;
supplying a first etching gas into the vacuum container, the first etching gas containing a first gas component for generating etching seeds of the etched layer when plasma is generated and a second gas component for generating an adsorption product by reacting with atoms of the silicon material constituting the etched layer;
generating plasma in the vacuum container to etch a portion of the surface of the etched layer exposed through the mask by the etching seeds generated by the first gas component;
supplying a second etching gas after stopping the etching by the first etching gas, the second etching gas containing the first gas component and a third gas component which is a fluorocarbon gas; and
generating plasma in the vacuum container to etch a portion of the surface of the etched layer exposed through the mask by the etching seeds generated by the first gas component.

6. The dry etching method according to claim 5, wherein the gas used for the etching is switched from the first etching gas to the second etching gas after an etching depth of the etched layer reaches 50% or more of a thickness of the etched layer and before the etching depth reaches an interface between the etched layer and the etching stop layer.

7. The dry etching method according to claim 5, wherein the third gas component contains at least one of C₄F₈, CHF₃, C₅H₈ and C₄F₆.

8. The dry etching method according to claim 5, wherein the first gas component is SF₆.

9. The dry etching method according to claim 5, wherein the etched layer is Si and the etching stop layer is SiO₂.

10. A dry etching apparatus, comprising:
a vacuum container in which a processing object is placed, the processing object being provided with a etching stop layer on which an etched layer made of a silicon material is formed, and a mask being formed on a surface of the etched layer
a first etching gas supply adapted to supply a first etching gas into the vacuum container, the first etching gas containing a first gas component for generating etching seeds of the etched layer and a second gas component for generating an adsorption product by reacting with atoms of the silicon material constituting the etched layer;
a second etching gas supply adapted to supply a second etching gas into the vacuum container, the second etching gas containing the first gas component and a third gas component which is a fluorocarbon gas;
a plasma generation source for generating plasma in the vacuum container; and
a controller for controlling the first and second etching gas supplies and the plasma generation source so as to continue a status where the first etching gas supply supplies the first etching gas into the vacuum container and the plasma generation source generates plasma in the vacuum container for a predetermined first time, and then to continue a status where the second etching gas supply supplies the second etching gas into the vacuum container and the plasma generation source generates plasma in the vacuum container for a predetermined second time.

11. The dry etching apparatus according to claim 10, wherein the first time is equal to or greater than a time in which an etching depth of the etched layer reaches 50% of the thickness of the etched layer, and is less than a time in which the etching depth reaches an interface between the etched layer and the etching stop layer.

12. The dry etching apparatus according to claim 10, further comprising a guide element for holding the processing object, wherein the guide element is made of fluororesin.
